(19) United States
(12) Patent Application Publication
(10) Pub. No.: US 2026/0150547 A1
(43) Pub. Date: May 28, 2026

(54) DISPLAY PANEL AND DISPLAY APPARATUS

(71) Applicant: WUHAN TIANMA MICROELECTRONICS CO., LTD., Wuhan (CN)

(72) Inventors: Yangzhao MA, Wuhan (CN); Meihong WANG, Wuhan (CN); Fengyun WU, Wuhan (CN)

(21) Appl. No.: 19/455,185

(22) Filed: Jan. 21, 2026

(30) Foreign Application Priority Data
Oct. 16, 2025 (CN) 202511483301.9

(51) Int. Cl. H10K 59/35; H10K 59/122; H10K 59/88

(52) U.S. Cl. CPC H10K 59/353; H10K 59/122; H10K 59/352; H10K 59/88

(57) ABSTRACT

Provided are a display panel and a display apparatus. The display panel includes: a pixel region; a substrate; and a pixel definition layer including a first, second, and third openings, corresponding to a first, second, and third orthographic sub-projection, respectively. In the pixel region, the first and second openings are arranged along a first direction, the third opening not overlapping them in the first direction; a minimum distance between the first and second orthographic sub-projections is a first distance; a distance between two closest points in the first and third orthographic sub-projections is a second distance, and edges on which the two points are located are curved edges; a distance between two closest points in the second and third orthographic sub-projections is a third distance, and edges on which the two points are located are curved edges; and the second and third distance are greater than the first distance

### CROSS-REFERENCE TO RELATED APPLICATION

The present application claims priority to Chinese Patent Application No. 202511483301.9, filed on Oct. 16, 2025, the content of which is incorporated herein by reference in its entirety.

### TECHNICAL FIELD

The present application relates to the field of display technologies, and in particular, to a display panel and a display apparatus.

### BACKGROUND

With the continuous development of display technologies, organic light emitting diode (OLED) display panels are widely used in various electronic products due to their advantages such as self-illumination, high brightness, low power consumption, and fast response.

In the structure of such display panels, the aperture ratio of sub-pixels and the spacing between adjacent sub-pixels are two important design parameters. Here, the design of the aperture ratio of sub-pixels is related to whether the display panels can meet the service life requirements, while the design of the spacing between adjacent sub-pixels is related to whether the display panels can meet the display requirements of low light leakage and low crosstalk.

However, based on the current design of sub-pixels in display panels, the mutual influence between the two parameters, namely the aperture ratio of sub-pixels and the spacing between adjacent sub-pixels, is relatively significant. For example, when the pixels per inch (PPI) of a display panel is relatively high, if it is desired that the design of the aperture ratio of sub-pixels enables the display panel to meet the service life specifications, the spacing between adjacent sub-pixels would need to be greatly reduced. However, a significant reduction in the spacing would severely exacerbate issues such as light leakage and crosstalk. Conversely, if it is desired that the design of the spacing enables the display panel to achieve better display specifications, this would conflict with the design of the aperture ratio of sub-pixels required to meet the service life demands.

### SUMMARY

In a first aspect, an embodiment of the present application provides a display panel, including
a display region and a non-display region, where the display region includes a plurality of pixel regions;
a substrate; and
a display layer located on one side of the substrate, where the display layer includes a pixel definition layer and a plurality of light-emitting devices, the pixel definition layer includes a plurality of openings, and at least a portion of a respective light-emitting device is located within one of the openings; the plurality of openings include a first opening, a second opening, and a third opening that respectively correspond to the light-emitting devices of different colors, and a respective pixel region includes one first opening, one second opening, and one third opening;
where orthographic projections of the openings onto the substrate are first orthographic projections, and the first orthographic projections include a first orthographic sub-projection corresponding to the first opening, a second orthographic sub-projection corresponding to the second opening, and a third orthographic sub-projection corresponding to the third opening;
in the pixel region, the first opening and the second opening are arranged along a first direction, the third opening does not overlap the first opening and the second opening in the first direction, a virtual straight line extending along a second direction and passing through a center point of the third orthographic sub-projection is located between the first orthographic sub-projection and the second orthographic sub-projection, and the second direction intersects with the first direction;
in the pixel region, a distance between two points that are closest to each other in the first orthographic sub-projection and the second orthographic sub-projection is a first distance; a distance between two points that are closest to each other in the first orthographic sub-projection and the third orthographic sub-projection is a second distance, and edges on which the two points are located are curved edges; and a distance between two points that are closest to each other in the second orthographic sub-projection and the third orthographic sub-projection is a third distance, and edges on which the two points are located are curved edges; and
the second distance is greater than the first distance, and the third distance is greater than the first distance.

In a second aspect, an embodiment of the present application further provides a display apparatus, including a display panel, where the display panel includes:
a display region and a non-display region, where the display region includes a plurality of pixel regions;
a substrate; and
a display layer located on one side of the substrate, where the display layer includes a pixel definition layer and a plurality of light-emitting devices, the pixel definition layer includes a plurality of openings, and at least a portion of a respective light-emitting device is located within one of the openings; the plurality of openings include a first opening, a second opening, and a third opening that respectively correspond to the light-emitting devices of different colors, and a respective pixel region includes one first opening, one second opening, and one third opening;
where orthographic projections of the openings onto the substrate are first orthographic projections, and the first orthographic projections include a first orthographic sub-projection corresponding to the first opening, a second orthographic sub-projection corresponding to the second opening, and a third orthographic sub-projection corresponding to the third opening;
in the pixel region, the first opening and the second opening are arranged along a first direction, the third opening does not overlap the first opening and the second opening in the first direction, a virtual straight line extending along a second direction and passing through a center point of the third orthographic sub-projection is located between the first orthographic sub-projection and the second orthographic sub-projection, and the second direction intersects with the first direction;
in the pixel region, a distance between two points that are closest to each other in the first orthographic sub-projection and the second orthographic sub-projection is a first distance; a distance between two points that are closest to each other in the first orthographic sub-projection and the third orthographic sub-projection is a second distance, and edges on which the two points are located are curved edges; and a distance between two points that are closest to each other in the second orthographic sub-projection and the third orthographic sub-projection is a third distance, and edges on which the two points are located are curved edges; and
the second distance is greater than the first distance, and the third distance is greater than the first distance.

### BRIEF DESCRIPTION OF DRAWINGS

To illustrate the technical solutions in the embodiments of the present application or the prior art more clearly, the accompanying drawings required to be used in the description of the embodiments or the prior art will be briefly introduced below. Apparently, the accompanying drawings in the following description are some embodiments of the present application, and those of skill in the art can obtain other drawings based on these accompanying drawings without creative efforts.

FIG. 1 is a schematic diagram of a display panel according to an embodiment of the present application;

FIG. 2 is a schematic diagram of openings according to an embodiment of the present application;

FIG. 3 is another schematic diagram of a display panel according to an embodiment of the present application;

FIG. 4 is another schematic diagram of openings according to an embodiment of the present application;

FIG. 5 is a schematic diagram of sub-pixels in the related art;

FIG. 6 is yet another schematic diagram of openings according to an embodiment of the present application;

FIG. 7 is yet another schematic diagram of a display panel according to an embodiment of the present application;

FIG. 8 is still another schematic diagram of a display panel according to an embodiment of the present application;

FIG. 9 is still another schematic diagram of a display panel according to an embodiment of the present application;

FIG. 10 is a schematic diagram of openings and grooves according to an embodiment of the present application;

FIG. 11 is another schematic diagram of openings and grooves according to an embodiment of the present application;

FIG. 12 is yet another schematic diagram of openings and grooves according to an embodiment of the present application;

FIG. 13 is still another schematic diagram of openings and grooves according to an embodiment of the present application;

FIG. 14 is still another schematic diagram of openings and grooves according to an embodiment of the present application;

FIG. 15 is still another schematic diagram of openings and grooves according to an embodiment of the present application;

FIG. 16 is still another schematic diagram of openings and grooves according to an embodiment of the present application;

FIG. 17 is a schematic diagram of openings, support posts, and grooves according to an embodiment of the present application;

FIG. 18 is a schematic diagram of openings, grooves, and dummy grooves according to an embodiment of the present application;

FIG. 19 is a cross-sectional view taken along an A1-A2 direction in FIG. 18;

FIG. 20 is still another schematic diagram of a display panel according to an embodiment of the present application;

FIG. 21 is still another schematic diagram of a display panel according to an embodiment of the present application; and

FIG. 22 is a schematic structural diagram of a display apparatus according to an embodiment of the present application.

### DESCRIPTION OF EMBODIMENTS

To better understand the technical solutions of the present application, the embodiments of the present application are described in detail below with reference to the accompanying drawings.

It should be clarified that the described embodiments are merely some of the embodiments of the present application rather than all the embodiments. Based on the embodiments of the present application, all other embodiments obtained by persons of ordinary skill in the art without creative efforts shall fall within the protection scope of the present application.

The terms used in the embodiments of the present application are merely for the purpose of describing specific embodiments and are not intended to limit the present application. As used in the embodiments of the present application and the appended claims, the singular forms “a/an”, “said”, and “the” are also intended to include the plural forms, unless the context clearly indicates otherwise.

It should be understood that the term “and/or” used herein is merely a relational descriptor for describing the association relationship between associated objects, meaning that three relationships may exist. For example, A and/or B may represent three situations: A exists alone, both A and B exist simultaneously, and B exists alone. In addition, the character “/” used herein generally indicates that the associated objects before and after it are in an “or” relationship.

Various modifications and variations can be made to the present application without departing from the spirit or scope of the present application, which will be apparent to those of skill in the art. Therefore, the present application is intended to cover modifications and variations of the present application that fall within the scope of the corresponding claims (the claimed technical solutions) and their equivalents. It should be noted that the implementations provided by the embodiments of the present application can be combined with each other without contradiction.

An embodiment of the present application provides a display panel, which may specifically be an OLED display panel.

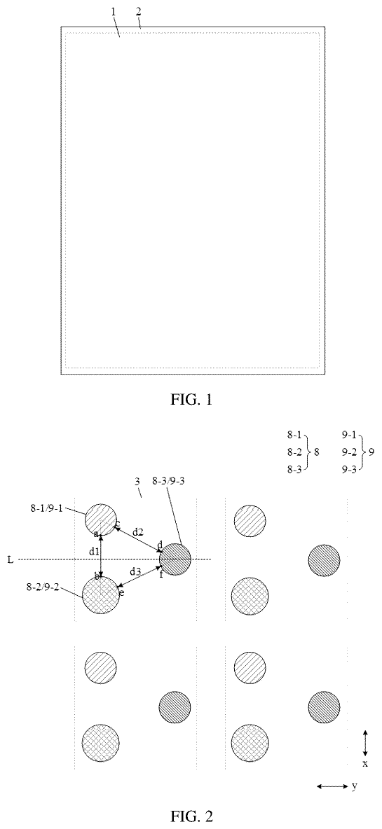

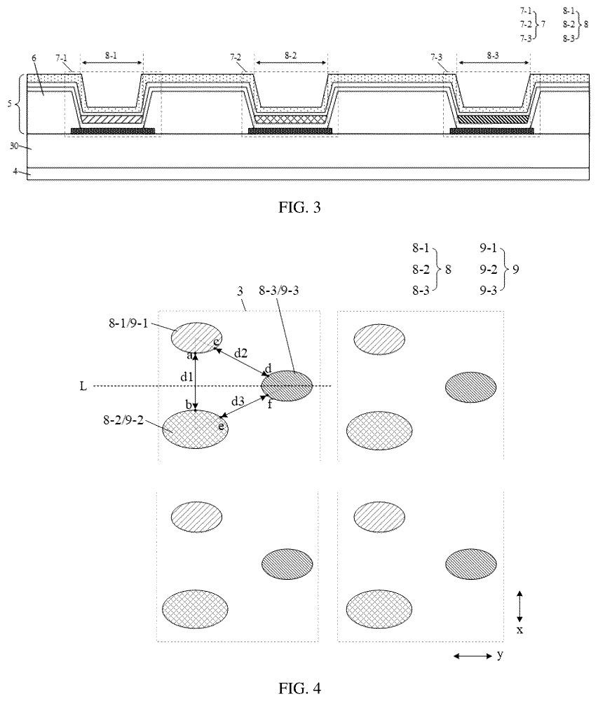

FIG. 1 is a schematic diagram of a display panel according to an embodiment of the present application, FIG. 2 is a schematic diagram of openings according to an embodiment of the present application, and FIG. 3 is another schematic diagram of a display panel according to an embodiment of the present application. As shown in FIGS. 1 to 3, the display panel includes a display region 1 and a non-display region 2. The display region 1 includes a plurality of pixel regions 3, for example, the pixel regions 3 may be regarded as smallest pixel units.

The display panel further includes a substrate 4 and a display layer 5 located on one side of the substrate 4. Here, the display layer 5 includes a pixel definition layer 6 and a plurality of light-emitting devices 7, the pixel definition layer 6 includes a plurality of openings 8, and at least a portion of a respective light-emitting device 7 is provided in one of the openings 8.

Orthographic projections of the openings 8 onto the substrate 4 are first orthographic projections 9. It should be noted that, due to process factors, the sidewall of the opening 8 may be an inclined sidewall, which will result in different widths of a bottom opening and a top opening of the opening 8. For example, referring to FIG. 3, the width of the bottom opening of the opening 8 is smaller than the width of the top opening of the opening 8. In this case, the first orthographic projection 9 corresponding to the opening 8 can be regarded as an orthographic projection corresponding to the bottom opening, that is, an edge of the first orthographic projection 9 is defined by an edge of the bottom opening of the opening 8.

The openings 8 include a first opening 8-1, a second opening 8-2, and a third opening 8-3, and the first opening 8-1, the second opening 8-2, and the third opening 8-3 respectively correspond to the light-emitting devices 7 of different colors. Correspondingly, the first orthographic projections 9 include a first orthographic sub-projection 9-1 corresponding to the first opening 8-1, a second orthographic sub-projection 9-2 corresponding to the second opening 8-2, and a third orthographic sub-projection 9-3 corresponding to the third opening 8-3.

The pixel region 3 includes one first opening 8-1, one second opening 8-2, and one third opening 8-3. In the pixel region 3, the first opening 8-1 and the second opening 8-2 are arranged along a first direction x, and the third opening 8-3 does not overlap the first opening 8-1 and the second opening 8-2 in the first direction x. Moreover, a virtual straight line L extending along a second direction y and passing through a center point of the third orthographic sub-projection 9-3 is located between the first orthographic sub-projection 9-1 and the second orthographic sub-projection 9-2, and the second direction y intersects the first direction x.

Moreover, referring to FIG. 3, in the pixel region 3, a distance between two points (point a and point b) that are closest to each other in the first orthographic sub-projection 9-1 and the second orthographic sub-projection 9-2 is a first distance d1. A distance between two points (point c and point d) that are closest to each other in the first orthographic sub-projection 9-1 and the third orthographic sub-projection 9-3 is a second distance d2, and edges on which the two points are located are curved edges. A distance between two points (point e and point f) that are closest to each other in the second orthographic sub-projection 9-2 and the third orthographic sub-projection 9-3 is a third distance d3, and edges on which the two points are located are curved edges. Here, the second distance is greater than the first distance, and the third distance is greater than the first distance.

It should be understood that the above-mentioned first distance d1 is the minimum distance between the region of the first opening 8-1 and the region of the second opening 8-2, the second distance d2 is the minimum distance between the region of the first opening 8-1 and the region of the third opening 8-3, and the third distance d3 is the minimum distance between the region of the second opening 8-2 and the region of the third opening 8-3.

In the related art, the opening shape of a sub-pixel is square. With this square design, the corners of adjacent openings are close to each other, which may result in adjacent openings being locally too close to each other and thereby more constricting the distance between adjacent openings. This may lead to a substantial mutual influence between the opening area and the opening spacing during design.

In contrast, in the embodiments of the present application, at least a portion of the edges of the first opening 8-1, the second opening 8-2, and the third opening 8-3 are curved edges. Such a curved-edge design can be used to avoid the problem that protruding parts such as corners (e.g., right angles) occupy the spacing between adjacent openings 8, thereby enabling more flexible adjustment of the opening spacing, which is conducive to reducing the mutual restriction between the opening area and the opening spacing during design. For example, such a curved-edge design is conducive to increasing the minimum distance between the third opening 8-3 and the first opening 8-1 and the minimum distance between the third opening 8-3 and the second opening 8-2 and utilizing the increase in these portions of spacing to enable the display panel to meet the display requirements of low light leakage and low crosstalk. Since the increase in these portions of opening spacing is more flexible, the restriction of the increased spacing on the design of the opening area is also reduced, enabling the area of at least one type of opening to be increased to achieve an improvement in service life, thereby enabling the display panel to achieve both better service life specifications and display specifications.

In a feasible implementation, referring again to FIG. 2, shapes of the first orthographic sub-projection 9-1, the second orthographic sub-projection 9-2, and the third orthographic sub-projection 9-3 are all circular.

With such a circular design, the minimum distance between any two adjacent orthographic sub-projections is equal to the distance between their centers minus the radii of the two circles, making it easier to control the minimum distance between adjacent openings 8. Moreover, the circular design of the opening 8 also helps to increase the spacing between adjacent openings 8 at other positions where they directly face each other. Said other positions where the adjacent openings 8 directly face each other refer to the positions within a directly facing region of two adjacent openings 8 other than the positions where the minimum distance is achieved, thereby being more conducive to reducing the leakage current and light-emitting crosstalk between the adjacent openings 8.

In addition, referring to FIG. 3, an array layer 30 is further provided between the substrate 4 and the display layer 5, and the array layer 30 includes various driving circuits and various connecting wires (not shown in the figure). Here, the driving circuits include pixel circuits, and the pixel circuits are electrically connected to the light-emitting devices 7 for providing driving current to the light-emitting devices 7.

In a feasible implementation, FIG. 4 is another schematic diagram of openings according to an embodiment of the present application. As shown in FIG. 4, a shape of at least one of the first orthographic sub-projection 9-1, the second orthographic sub-projection 9-2, and the third orthographic sub-projection 9-3 is elliptical.

Here, with such an elliptical design, the first orthographic sub-projection 9-1, the second orthographic sub-projection 9-2, and/or the third orthographic sub-projection 9-3 can be designed to lie flat, that is, the long axis extends along the second direction y.

Such an elliptical design can also utilize an elliptical curved edge to avoid the problem that protruding parts such as corners occupy the spacing between adjacent openings 8, thereby enabling more flexible adjustment of the opening spacing, which is conducive to reducing the mutual restriction between the opening area and the opening spacing during design.

In a feasible implementation, referring to FIGS. 2 and 3, the light-emitting devices 7 include a red light-emitting device 7-1, a green light-emitting device 7-2, and a blue light-emitting device 7-3. At least a portion of the red light-emitting device 7-1 is located within the first opening 8-1, at least a portion of the green light-emitting device 7-2 is located within the second opening 8-2, and at least a portion of the blue light-emitting device 7-3 is located within the third opening 8-3.

Here, an area of the second orthographic sub-projection 9-2 is greater than an area of the first orthographic sub-projection 9-1, and/or the area of the second orthographic sub-projection 9-2 is greater than an area of the third orthographic sub-projection 9-3. For example, in one type of structure, the area of the first orthographic sub-projection 9-1 is equal to the area of the third orthographic sub-projection 9-3, and the area of the second orthographic sub-projection 9-2 is greater than the area of the first orthographic sub-projection 9-1 and the area of the third orthographic sub-projection 9-3, respectively.

The overall brightness of a display picture of a screen depends more on the brightness of green light. Therefore, in the embodiments of the present application, the area of the region of the second opening 8-2 corresponding to the green light-emitting device 7-2 can be set to be larger to reduce its current density, thereby more specifically addressing the risk of excessively rapid degradation of the display panel′ service life caused by the high brightness contribution of the green sub-pixel, and ultimately optimizing the overall service life of the screen.

In this regard, the inventors further tested the structures in the present application and the related art.

FIG. 5 is a schematic diagram of sub-pixels in the related art. As shown in FIG. 5, in the related art, a first opening 101, a second opening 102, and a third opening 103 are all designed in a square shape.

In the conventional design, the minimum distance k1 between the first opening 101 and the second opening 102 is 17 μm, the minimum distance k2 between the first opening 101 and the third opening 103 is 17 μm, and the minimum distance k3 between the second opening 102 and the third opening 103 is 17 μm. With this design, the distance between adjacent openings is too small, resulting in poor improvement of issues such as light leakage and crosstalk in the display panel.

When it is necessary to increase the opening spacing so that the minimum distance between at least some adjacent openings reaches 20 μm, based on the design in the related art, when the aforementioned k1, k2, and k3 are all increased to 20 μm, the aperture ratios of the three types of openings can be designed to be as follows: the first opening 101 has an aperture ratio of 2.84%, the second opening 102 has an aperture ratio of 3.73%, and the third opening 103 has an aperture ratio of 3.73%. In this case, the equivalent aperture ratio for white light is 11.56%. However, in this design, the aperture ratio of the second opening 102 (corresponding to the green sub-pixel) is relatively low, resulting in poor service life of the display panel. After testing, it was found that when the display panel with this design continuously operates at a brightness of 1000 nits, the duration for its brightness to decay from 1000 nits to 950 nits (i.e., to 95% of the initial brightness) is 650 hours.

In contrast, based on the design in the embodiments of the present application, when the first distance d1 is 17 μm, the second distance d2 is increased to 22.3 μm, and the third distance d3 is increased to 20.3 μm, the aperture ratios of the three types of openings 8 can be designed to be as follows: the first opening 8-1 has an aperture ratio of 3.03%, the second opening 8-2 has an aperture ratio of 4.62%, and the third opening 8-3 has an aperture ratio of 3.03%. In this case, the equivalent aperture ratio for white light is 10.68%. In this design, the aperture ratio of the second opening 8-2 (corresponding to green sub-pixel) is significantly increased, resulting in a significant improvement of the service life of the display panel. After testing, it was found that when the display panel with this design continuously operates at a brightness of 1000 nits, the duration for its brightness to decay from 1000 nits to 950 nits (i.e., to decay to 95% of the initial brightness) is increased to 800 hours.

It can be seen that, compared with the related art, by adopting the technical solutions according to the embodiments of the present application, while effectively improving issues such as light leakage and crosstalk by increasing the opening spacing, the service life of the display panel can also be significantly improved.

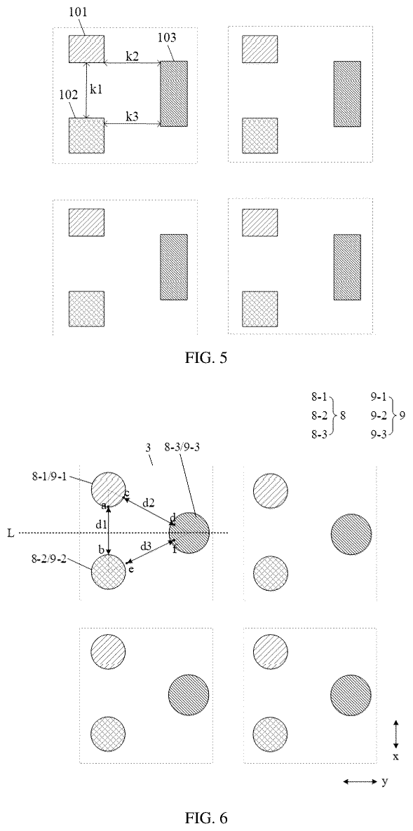

Of course, in other optional implementations of the present application, the areas of the first orthographic sub-projection 9-1, the second orthographic sub-projection 9-2, and the third orthographic sub-projection 9-3 can also be of other designs. For example, FIG. 6 is yet another schematic diagram of openings according to an embodiment of the present application. As shown in FIG. 6, the area of the second orthographic sub-projection 9-2 is equal to the area of the first orthographic sub-projection 9-1, and the area of the third orthographic sub-projection 9-3 is greater than the area of the second orthographic sub-projection 9-2 and the area of the first orthographic sub-projection 9-1.

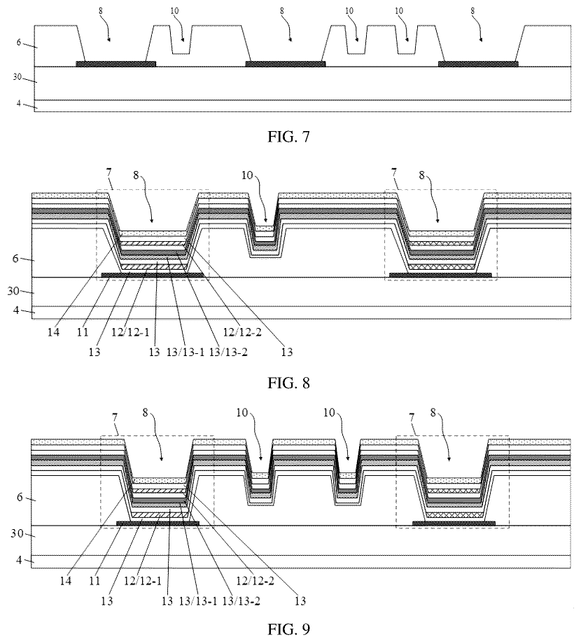

In a feasible implementation, FIG. 7 is yet another schematic diagram of a display panel according to an embodiment of the present application, FIG. 8 is still another schematic diagram of a display panel according to an embodiment of the present application, and FIG. 9 is still another schematic diagram of a display panel according to an embodiment of the present application. As shown in FIGS. 7 to 9, the pixel definition layer 6 further includes grooves 10, and the grooves 10 are provided between at least some adjacent openings 8.

The grooves 10 are configured to improve the issue of light leakage of the light-emitting devices 7. Specifically, referring to FIGS. 8 and 9, each light-emitting device 7 includes an anode 11, a light-emitting layer 12, a common layer 13, and a cathode 14, and the common layers 13 corresponding to the light-emitting devices 7 are connected to each other to form a full-surface structure.

Here, the common layer 13 is provided between the light-emitting layer 12 and the anode 11, and this portion of the common layer 13 may include a hole injection layer (HIL), a hole transport layer (HTL), etc.

And/or, the common layer 13 is provided between the light-emitting layer 12 and the cathode 14, and this portion of the common layer 13 may include an electron transport layer (ETL), an electron injection layer (EIL), etc.

And/or, referring to FIGS. 8 and 9, the light-emitting device 7 may be a series-connected light-emitting device. In such a light-emitting device, the light-emitting layer 12 includes a first light-emitting layer 12-1 and a second light-emitting layer 12-2. The common layer 13 may also be provided between the first light-emitting layer 12-1 and the second light-emitting layer 12-2, and this portion of the common layer 13 may include an n-charge generation layer (NCGL) 13-1 and a p-charge generation layer (PCGL) 13-2.

The common layers 13 of the light-emitting devices 7 are connected to each other, so that the common layers 13 can provide a transmission path for lateral leakage current, causing the light-emitting devices 7 that should not emit light to emit light under the effect of the lateral leakage current, resulting in the issue of sub-pixel light leakage, which will seriously affect the display effect at low grayscale.

However, by providing the grooves 10 between at least some adjacent openings 8, the grooves 10 can be used to increase the path length of the common layer 13 and reduce the thickness of the common layer 13 at the inner walls of the grooves 10, such that the load of this portion of the common layer 13 between adjacent openings 8 is increased, thereby effectively extending or cutting off the transmission path of the lateral leakage current at this position, blocking the transmission of leakage current, and avoiding the occurrence of light leakage.

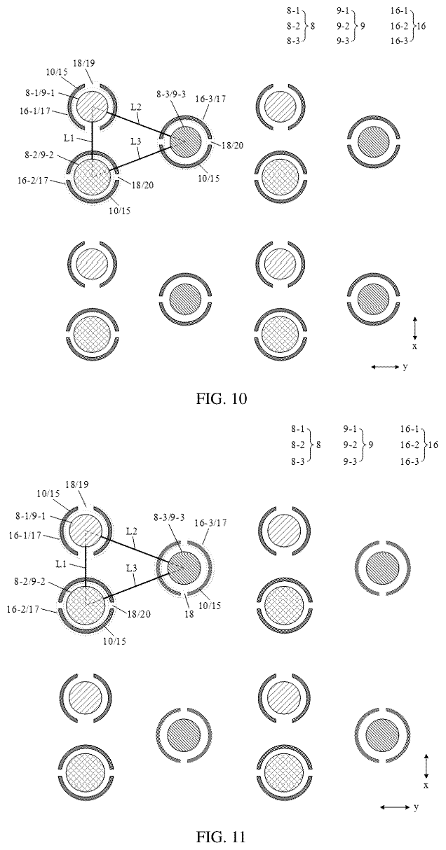

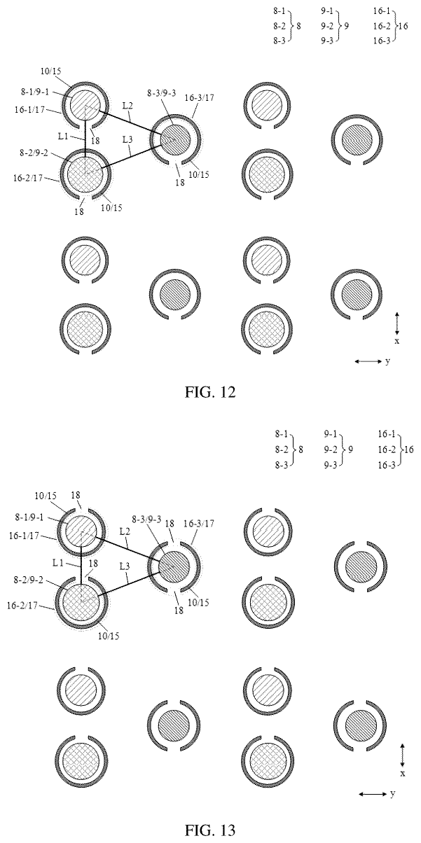

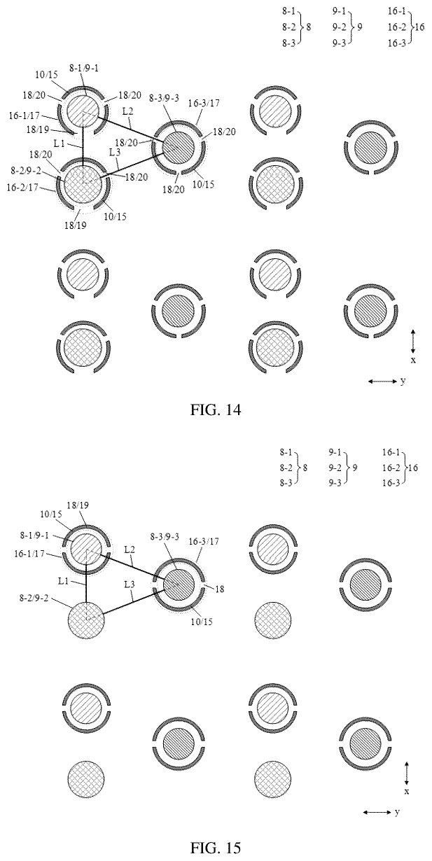

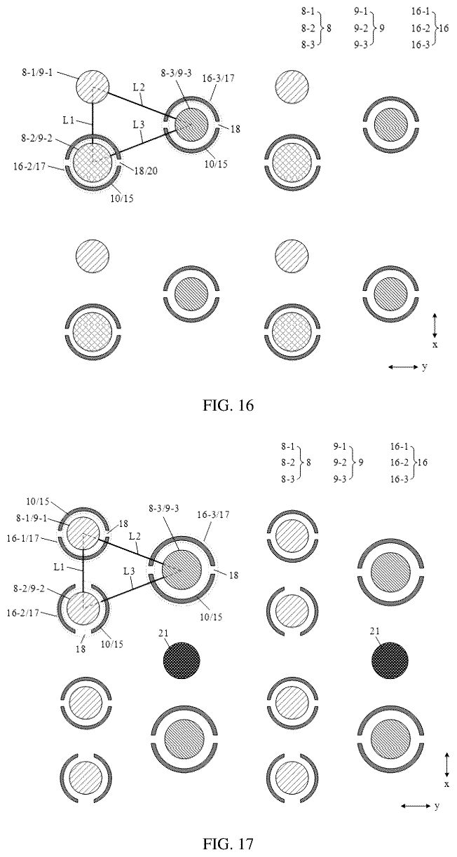

FIG. 10 is a schematic diagram of openings and grooves according to an embodiment of the present application, FIG. 11 is another schematic diagram of openings and grooves according to an embodiment of the present application, FIG. 12 is yet another schematic diagram of openings and grooves according to an embodiment of the present application, FIG. 13 is still another schematic diagram of openings and grooves according to an embodiment of the present application, FIG. 14 is still another schematic diagram of openings and grooves according to an embodiment of the present application, FIG. 15 is still another schematic diagram of openings and grooves according to an embodiment of the present application, and FIG. 16 is still another schematic diagram of openings and grooves according to an embodiment of the present application. As shown in FIGS. 10 to 16, in the pixel region 3, a first dummy connecting line L1 is provided between two points (point a and point b) that are closest to each other in the first orthographic sub-projection 9-1 and the second orthographic sub-projection 9-2, a second dummy connecting line L2 is provided between two points that are closest to each other in the first orthographic sub-projection 9-1 and the third orthographic sub-projection 9-3, and a third dummy connecting line L3 is provided between two points that are closest to each other in the second orthographic sub-projection 9-2 and the third orthographic sub-projection 9-3.

Orthographic projections of the grooves 10 onto the substrate 4 are second orthographic projections 15. Here, a number of the second orthographic projections 15 passed through by the first dummy connecting line L1 is less than or equal to a number of the second orthographic projections 15 passed through by the second dummy connecting line L2, and the number of the second orthographic projections 15 passed through by the first dummy connecting line L1 is less than or equal to a number of the second orthographic projections 15 passed through by the third dummy connecting line L3.

It can be understood that the position of any of the above-mentioned dummy connecting lines is the position where the two openings 8 are closest to each other. That is, the position of the first dummy connecting line L1 is the position where the distance between the first opening 8-1 and the second opening 8-2 is minimized, the position of the second dummy connecting line L2 is the position where the distance between the first opening 8-1 and the third opening 8-3 is minimized, and the position of the third dummy connecting line L3 is the position where the distance between the second opening 8-2 and the third opening 8-3 is minimized. The number of the second orthographic projections 15 passed through by any of the dummy connecting lines refers to the number of the grooves 10 by which adjacent openings 8 are spaced at the positions where the minimum distance therebetween is achieved.

In the case where the grooves 10 are not provided, at the positions where the minimum distance between adjacent openings 8 is achieved, the extension path of the lateral leakage current is the shortest; thus, these positions are more prone to causing the light leakage issue.

In a design of an embodiment of the present application, referring to FIGS. 10 to 13, the number of the grooves 10 by which different openings 8 are spaced at the positions where the minimum distance therebetween is achieved can also be designed differently according to the different designs of the minimum distance between different openings 8. Specifically, the minimum distance between the third opening 8-3 and the first opening 8-1 and the minimum distance between the third opening 8-3 and the second opening 8-2 are larger, and these distances can better meet the requirements of the dual-groove or multi-groove designs for the opening spacing. Therefore, the number of the grooves 10 by which the third opening 8-3 and the first opening 8-1 are spaced at the positions where the minimum distance therebetween is achieved as well as the number of the grooves 10 by which the third opening 8-3 and the second opening 8-2 are spaced at the positions where the minimum distance therebetween is achieved can be set to be larger to use these grooves 10 for multi-layer protection, thereby better blocking the lateral leakage current between the third opening 8-3 and the first opening 8-1 at the positions where the minimum distance therebetween is achieved, and better blocking the lateral leakage current between the third opening 8-3 and the second opening 8-2 at the positions where the minimum distance therebetween is achieved, thereby improving light leakage. Meanwhile, since the minimum distance between the first opening 8-1 and the second opening 8-2 is smaller, and with this distance, the requirements of the multi-groove design for the opening spacing cannot be met, the number of the grooves 10 by which the first opening 8-1 and the second opening 8-2 are spaced at the positions where the minimum distance therebetween is achieved can be set to be smaller to avoid the grooves 10 being too close to the first opening 8-1 and the second opening 8-2, which would otherwise result in the grooves 10 being connected to the openings 8 due to process factors, and in turn to avoid the design of the grooves 10 affecting the normal light emission through the first opening 8-1 and the second opening 8-2.

Alternatively, in another design of the embodiments of the present application, referring to FIG. 14, the number of the grooves 10 by which the first opening 8-1 and the second opening 8-2 are spaced at the positions where the minimum distance therebetween is achieved, the number of the grooves 10 by which the first opening 8-1 and the third opening 8-3 are spaced at the positions where the minimum distance therebetween is achieved, and the number of the grooves 10 by which the second opening 8-2 and the third opening 8-3 are spaced at the positions where the minimum distance therebetween is achieved can also be set to be equal. After the grooves 10 are provided, the cathodes 14 are recessed in the grooves 10, which will generate voltage drops. This structure can improve the consistency of the cathode signal voltage drops between different adjacent openings 8.

In a feasible implementation, referring to FIGS. 10 to 13, 15, and 16, the number of the second orthographic projections 15 passed through by the second dummy connecting line L2 is greater than the number of the second orthographic projections 15 passed through by the first dummy connecting line L1, and/or, the number of the second orthographic projections 15 passed through by the third dummy connecting line L3 is greater than the number of the second orthographic projections 15 passed through by the first dummy connecting line L1.

That is, the number of the grooves 10 by which the first opening 8-1 and the third opening 8-3 are spaced at the positions where the minimum distance therebetween is achieved is greater than the number of the grooves 10 by which the first opening 8-1 and the second opening 8-2 are spaced at the positions where the minimum distance therebetween is achieved, and/or, the number of the grooves 10 by which the second opening 8-2 and the third opening 8-3 are spaced at the positions where the minimum distance therebetween is achieved is greater than the number of the grooves 10 by which the first opening 8-1 and the second opening 8-2 are spaced at the positions where the minimum distance therebetween is achieved.

In conjunction with the foregoing analysis, this structure can also adopt a differentiated design for the number of the grooves 10 by which different openings 8 are spaced at the positions where the minimum distance therebetween is achieved, according to the differences in the minimum distances between different openings 8, thereby enabling the minimum distances between different adjacent openings 8 to match the requirements for opening spacing corresponding to the number of the grooves 10 spaced therebetween.

In a feasible implementation, referring to FIGS. 10 to 14, the pixel definition layer 6 includes groove units 16, and a respective groove unit 16 includes at least one groove 10 and surrounds one opening 8.

Orthographic projections of the groove units 16 onto the substrate 4 are third orthographic projections 17, a respective third orthographic projection 17 includes at least one second orthographic projection 15, and at least some third orthographic projections 17 have a notch 18.

Here, the fact that the third orthographic projections 17 have a notch 18 means that a gap is provided between the ends of the groove(s) 10 in each of the groove units 16. In one case, at least some groove units 16 each include only one groove 10, this groove 10 is a non-closed pattern, and a gap is provided between two ends of the groove 10, which in turn enables the corresponding third orthographic projection 17 to have one notch 18. Alternatively, in another case, at least some groove units 16 each include at least two grooves 10, and gaps are provided between the ends of adjacent grooves 10, which in turn enables the corresponding third orthographic projection 17 to have at least two notches 18.

Here, the first dummy connecting line L1 passes through the notch 18 of at least one third orthographic projection 17.

That is to say, the gap in at least one groove unit 16 is provided between the positions where the minimum distance between the first opening 8-1 and the second opening 8-2 is achieved. Exemplarily, referring to FIG. 10, the groove units 16 include a first groove unit 16-1 surrounding the first opening 8-1 and a second groove unit 16-2 surrounding the second opening 8-2, the gap in the first groove unit 16-1 is provided between the positions where the minimum distance between the first opening 8-1 and the second opening 8-2 is achieved, thereby causing the grooves 10 in the first groove unit 16-1 to avoid these positions and causing only the groove 10 in the second groove unit 16-2 to be provided between these positions, and preventing insufficient space due to an excessive number of the grooves 10 provided between these positions.

In a feasible implementation, referring to FIG. 10, the notch 18 includes a first notch 19 and a second notch 20, and the first dummy connecting line L1 passes through the first notch 19 but does not pass through the second notch 20, where a length of the first notch 19 in an extension direction of the third orthographic projection 17 in which the first notch 19 is located is greater than a length of the second notch 20 in the extension direction of the third orthographic projection 17 in which the second notch 20 is located.

Here, the first notch 19 and the second notch 20 can be located in a same third orthographic projection 17 or in different third orthographic projections 17. For example, as illustrated in FIG. 10, the third orthographic projection 17 corresponding to the first groove unit 16-1 includes the first notch 19, and the third orthographic projection 17 corresponding to the second groove unit 16-2 includes the second notch 20. Taking this structure as an example, since the first notch 19 is provided between the positions where the first opening 8-1 and the second opening 8-2 are closest to each other, the size of the first notch 19 can be set to be slightly larger, thereby allowing the first groove unit 16-1 to have greater avoidance at this position and preventing the occupation of space at this position. Meanwhile, since the second notch 20 is not provided between these positions, the size of the second notch 20 can be designed to be smaller, allowing the grooves 10 forming the second notch 20 to provide greater protection for the region of the opening 8 and to block the lateral leakage current in more orientations.

In a feasible implementation, referring again to FIG. 10, in at least one third orthographic projection 17, the notch 18 is located on at least one side of the first orthographic projection 9 surrounded by the notch 18 in the first direction x; and in at least one third orthographic projection 17, the notch 18 is located on at least one side of the first orthographic projection 9 surrounded by the notch 18 in the second direction y.

The deposition of the cathodes 14 in the grooves 10 causes the cathode signal voltage drop at the positions of the grooves 10 to be relatively large. By providing gaps in some groove units 16 on at least one side in the horizontal direction and providing gaps in some groove units 16 on at least one side in the vertical direction, the consistency of the cathode signal voltage drop in both the horizontal and vertical directions can be improved, thereby helping to improve display uniformity.

In a feasible implementation, referring to FIGS. 11 to 13, the groove units 16 include a first groove unit 16-1 surrounding the first opening 8-1 and a second groove unit 16-2 surrounding the second opening 8-2.

Here, the third orthographic projection 17 corresponding to at least one first groove unit 16-1 has one notch 18, and/or the third orthographic projection 17 corresponding to at least one first groove unit 16-1 has at least two notches 18.

The third orthographic projection 17 corresponding to at least one second groove unit 16-2 has one notch 18, and/or the third orthographic projection 17 corresponding to at least one second groove unit 16-2 has at least two notches 18.

Specifically, when the third orthographic projection 17 corresponding to the first groove unit 16-1 (or the second groove unit 16-2) has one notch 18, it means that the first groove unit 16-1 (or the second groove unit 16-2) includes only one groove 10, and the groove 10 surrounds the first opening 8-1 (or the second opening 8-2) in a non-closed manner. When the third orthographic projection 17 corresponding to the first groove unit 16-1 (or the second groove unit 16-2) has at least two notches 18, it means that the first groove unit 16-1 (or the second groove unit 16-2) includes at least two grooves 10.

In this arrangement, both the periphery of the first opening 8-1 and the periphery of the second opening 8-2 are surrounded by the groove units 16, and by only providing gaps in the two types of groove units 16 and providing the gaps at the positions where the minimum distance between the first opening 8-1 and the second opening 8-2 is achieved, the number of the grooves 10 provided at these positions is reduced. As such, there are still the grooves 10 at the positions where the first opening 8-1 and the second opening 8-2 do not directly face each other to provide protection, thereby using the grooves 10 at these positions to block the lateral leakage current and improve the phenomenon of light leakage.

Further, referring to FIGS. 10 and 11, the third orthographic projection 17 corresponding to the first groove unit 16-1 has two notches 18, and the third orthographic projection 17 corresponding to the second groove unit 16-2 has two notches 18.

Here, in the third orthographic projection 17 corresponding to the first groove unit 16-1, the two notches 18 are located on opposite sides of the first orthographic sub-projection 9-1 in a third direction, respectively; and in the third orthographic projection 17 corresponding to the second groove unit 16-2, the two notches 18 are located on opposite sides of the second orthographic sub-projection 9-2 in a fourth direction, respectively. Here, one of the third direction and the fourth direction is parallel to the first direction x, and the other one of the third direction and the fourth direction is parallel to the second direction y.

Exemplarily, referring to FIGS. 10 and 11, the third direction is parallel to the first direction x, and the fourth direction is parallel to the second direction y. In the third orthographic projection 17 corresponding to the first groove unit 16-1, the two notches 18 are located on opposite sides of the first orthographic sub-projection 9-1 in the first direction x, and in the third orthographic projection 17 corresponding to the second groove unit 16-2, the two notches 18 are located on opposite sides of the second orthographic sub-projection 9-2 in the second direction y.

Alternatively, in another structure, the third direction is parallel to the second direction y, and the fourth direction is parallel to the first direction x. In the third orthographic projection 17 corresponding to the first groove unit 16-1, the two notches 18 are located on opposite sides of the first orthographic sub-projection 9-1 in the second direction y, and in the third orthographic projection 17 corresponding to the second groove unit 16-2, the two notches 18 are located on opposite sides of the second orthographic sub-projection 9-2 in the first direction x.

In this structure, a single-groove design is adopted between the positions where the minimum distance between the first opening 8-1 and the second opening 8-2 is achieved, and this design matches the magnitude of the minimum distance between the first opening 8-1 and the second opening 8-2. Moreover, between these positions, the groove 10 provided therebetween can also be used to block the lateral leakage current, thereby reducing the influence of leakage current between the first opening 8-1 and the second opening 8-2.

Further, when the second opening 8-2 corresponds to a green light-emitting device, referring to FIGS. 10 and 11, the two notches 18 in the third orthographic projection 17 corresponding to the first groove unit 16-1 can be located on opposite sides of the first orthographic sub-projection 9-1 in the third direction (the first direction x), while the two notches 18 in the third orthographic projection 17 corresponding to the second groove unit 16-2 can be located on opposite sides of the second orthographic sub-projection 9-2 in the fourth direction (the second direction y).

In this structure, it is the gap in the first groove unit 16-1 that is provided between the positions where the minimum distance between the first opening 8-1 and the second opening 8-2 is achieved.

As noted above, the gap (corresponding to the first notch 19) provided between the first opening 8-1 and the second opening 8-2 may have a larger size, while the gap (corresponding to the second notch 20) not provided between the first opening 8-1 and the second opening 8-2 may have a smaller size.

When the second opening 8-2 corresponds to a green light-emitting device, since green light contributes the most to brightness, if light leakage occurs in the green light-emitting device 7-2, it is easier to be perceived by human eyes, causing a greater impact. Therefore, the gaps of the second groove unit 16-2 are provided on the lateral opposite sides, that is, these gaps is not provided between the first opening 8-1 and the second opening 8-2, which can enable the extension length of these gaps to be designed to be smaller, correspondingly enabling the extension length of the grooves 10 in the second groove unit 16-2 to be larger, so as to enable this portion of grooves 10 to provide more comprehensive protection for the second opening 8-2 and prevent the light leakage of the second opening 8-2 from causing a significant impact on display.

Alternatively, referring to FIGS. 12 and 13, the third orthographic projection 17 corresponding to the first groove unit 16-1 has one notch 18, and the third orthographic projection 17 corresponding to the second groove unit 16-2 has one notch 18.

In the third orthographic projections 17 corresponding to the first groove unit 16-1 and the second groove unit 16-2, each notch 18 is located on a same side of the first orthographic projection 9 surrounded by the notch in the first direction x.

For example, the opening 8 includes an upper side and a lower side that are opposite in the first direction x. In a structure, referring to FIG. 12, the gap in the first groove unit 16-1 is located on the lower side of the first opening 8-1, and the gap in the second groove unit 16-2 is located on the lower side of the second opening 8-2. Alternatively, in another structure, referring to FIG. 13, the gap in the first groove unit 16-1 is located on the upper side of the first opening 8-1, and the gap in the second groove unit 16-2 is located on the upper side of the second opening 8-2.

In this structure, the gap in one of the first groove unit 16-1 and the second groove unit 16-2 is provided between the first opening 8-1 and the second opening 8-2 in a same pixel region 3, while the gap in the other one of the first groove unit 16-1 and the second groove unit 16-2 is provided between the first opening 8-1 and the second opening 8-2 in different pixel regions 3. In this design, the number of the gaps in the first groove unit 16-1 and the second groove unit 16-2 is relatively small, and the extension length of the grooves 10 is larger. Therefore, the blocking effect on the lateral leakage currents at the peripheries of the first opening 8-1 and the second opening 8-2 is better, which can more effectively prevent the phenomenon of light leakage of the light-emitting devices 7 corresponding to the two types of openings 8.

In a feasible implementation, referring to FIGS. 10 to 16, the groove units 16 further include a third groove unit 16-3 surrounding one third opening 8-3.

The third groove unit 16-3 includes at least one groove 10, that is, the third orthographic projection 17 corresponding to the third groove unit 16-3 has at least one notch 18.

The third groove unit 16-3 can be used to block the lateral leakage current at the periphery of the third opening 8-3, reducing the risk of light leakage of the light-emitting device 7 corresponding to the third opening 8-3. Meanwhile, the third groove unit 16-3 has a gap, and the gap can be used to enhance the flow of the cathode signal and reduce the influence of the cathode signal voltage drop.

In a feasible implementation, referring to FIGS. 10 and 11, in the third orthographic projection 17 corresponding to at least one of the first groove unit 16-1 and the second groove unit 16-2, the notch 18 is located on at least one side of the first orthographic projection 9 surrounded by the notch in the third direction.

In the third orthographic projection 17 corresponding to the third groove unit 16-3, the notch 18 is located on at least one side of the third orthographic sub-projection 9-3 in the fourth direction.

Here, one of the third direction and the fourth direction is parallel to the first direction x, and the other one of the third direction and the fourth direction is parallel to the second direction y.

For example, referring to FIG. 10, the third direction is parallel to the first direction x, and the fourth direction is parallel to the second direction y. The gaps in the first groove unit 16-1 are located on opposite sides of the first opening 8-1 in the first direction x, the gaps in the second groove unit 16-2 are located on opposite sides of the second opening 8-2 in the second direction y, and the gaps in the third groove unit 16-3 are located on opposite sides of the third opening 8-3 in the second direction y.

In the above design, the orientations of the gaps in the third groove unit 16-3 are at least different from the orientations of the gaps in the first groove unit 16-1 or the second groove unit 16-2. These gaps with different orientations can improve the consistency of the cathode signal voltage drop in both the horizontal and vertical directions, thereby helping to improve the uniformity of display.

For the various structures illustrated in FIGS. 10 to 13, the present application has also tested the light leakage conditions under these structures.

In the structures illustrated in FIGS. 10 and 11, the first groove unit 16-1, the second groove unit 16-2, and the third groove unit 16-3 each include two gaps. Here, a single-groove design is applied between the positions where the minimum distance between the first opening 8-1 and the second opening 8-2 is achieved; a dual-groove design is applied between the positions where the minimum distance between the first opening 8-1 and the third opening 8-3 is achieved; and a dual-groove design is applied between the positions where the minimum distance between the second opening 8-2 and the third opening 8-3 is achieved.

Here, the light stealing conditions of the structure illustrated in FIG. 10 can be found in Table 1, and the light stealing conditions of the structure illustrated in FIG. 11 can be found in Table 2.

Here, in the tables provided in the embodiments of the present application, in a “P@Q image”, Q refers to a target test image, and P refers to observed non-target sub-pixels. The “P@Q image” specifically denotes a test performed on the light leakage conditions of P-color sub-pixels under a Q-color image. Both the specific values and percentages corresponding to the “P@Q image” in the tables are evaluations of the light leakage degree of the P-color sub-pixels under the Q-color image. Here, the meaning of a specific value corresponding to the “P@Q image” is (peak intensity of the P-color in the spectrum of the low-brightness Q-color image-peak intensity of the P-color in the spectrum of the high-brightness Q-color image)/peak intensity of the P-color in the spectrum of the high-brightness Q-color image. Here, for example, the low brightness may be 0.1 nit, and the high brightness may be 1000 nit. The percentage corresponding to the “P@Q image” is used to measure the uniformity of the light leakage degree of all P-color sub-pixels. For example, during the test, 100 test points are selected in the Q-color image to detect the light leakage condition of each test point, and in turn the uniformity of the light leakage degree of all P-color sub-pixels is reflected based on the light leakage degree of these 100 test points.

Exemplarily, in Table 1, the “R@B image” denotes a test performed on the light leakage conditions of red sub-pixels under a blue image. The corresponding value 0.0032 is calculated as (peak intensity of red in the spectrum of the low-brightness blue image-peak intensity of red in the spectrum of the high-brightness blue image)/peak intensity of red in the spectrum of the high-brightness blue image, and the corresponding 99.5% indicates that the uniformity of the light leakage degree of different red sub-pixels under the blue image is 99.5%.

As can be seen from Tables 1 and 2, under these two structures, the light leakage conditions of the sub-pixels are relatively weak, and the light leakage conditions can be effectively improved.

TABLE 1

| Light Leakage Simulation | | The structure illustrated in FIG. 10 |
|---|---|---|
| Light Leakage | R@B image | 0.0032 |
| | G@B image | 0.0036 |
| | R@G image | 0.0043 |
| Uniformity of | R@B image | 99.5% |
| Light Leakage | G@B image | 99.5% |
| | R@G image | 99.5% |

TABLE 2

| Light Leakage Simulation | | The structure illustrated in FIG. 11 |
|---|---|---|
| Light Leakage | R@B image | 0.0045 |
| | G@B image | 0.0026 |
| | R@G image | 0.0040 |
| Uniformity of | R@B image | 99.5% |
| Light Leakage | G@B image | 99.5% |
| | R@G image | 99.5% |

In the structures illustrated in FIGS. 12 and 13, the first groove unit 16-1 and the second groove unit 16-2 each include one gap. The difference is that in the structure of FIG. 12, the third groove unit 16-3 includes one gap, while in the structure of FIG. 13, the third groove unit 16-3 includes two gaps. Here, both structures adopt a single-groove design between the positions where the minimum distance between the first opening 8-1 and the second opening 8-2 is achieved, a dual-groove design between the positions where the minimum distance between the first opening 8-1 and the third opening 8-3 is achieved, and a dual-groove design between the positions where the minimum distance between the second opening 8-2 and the third opening 8-3 is achieved.

Here, the light leakage conditions of the structure illustrated in FIG. 12 can be found in Table 3, and the light leakage conditions of the structure illustrated in FIG. 13 can be found in Table 4.

TABLE 3

| Light Leakage Simulation | | The structure illustrated in FIG. 12 |
|---|---|---|
| Light Leakage | R@B image | 0.0029 |
| | G@B image | 0.0028 |
| | R@G image | 0.0019 |
| Uniformity of | R@B image | 99.5% |
| Light Leakage | G@B image | 99.5% |
| | R@G image | 99.5% |

TABLE 4

| Light Leakage Simulation | | The structure illustrated in FIG. 13 |
|---|---|---|
| Light Leakage | R@B image | 0.0034 |
| | G@B image | 0.0028 |
| | R@G image | 0.0027 |
| Uniformity of | R@B image | 99.5% |
| Light Leakage | G@B image | 99.5% |
| | R@G image | 99.5% |

As can be seen from a comparison of Tables 3 and 4, under these two structures, the light leakage conditions of the sub-pixels are relatively weak, and the light leakage conditions can be effectively improved. Moreover, as can be seen from the data comparison, compared with the structures illustrated in FIGS. 10 and 11, in the structures illustrated in FIGS. 12 and 13, because the first groove unit 16-1 and the second groove unit 16-2 each include only one gap, the blocking effect on lateral leakage currents is greater. The light leakage degrees of red sub-pixels and green sub-pixels under a blue image are lower, and the light leakage degree of red sub-pixels under a green image is also lower.

In a feasible implementation, referring to FIG. 14, the third orthographic projection 17 corresponding to the first groove unit 16-1 has at least three notches 18, the third orthographic projection 17 corresponding to the second groove unit 16-2 has at least three notches 18, and the third orthographic projection 17 corresponding to the third groove unit 16-3 has at least three notches 18.

Here, in the third orthographic projections 17 corresponding to the first groove unit 16-1 and the second groove unit 16-2, the first dummy connecting line L1 passes through the notch 18 in one of the third orthographic projections 17 and the second orthographic projection 15 in the other one of the third orthographic projections 17. In the third orthographic projections 17 corresponding to the first groove unit 16-1 and the third groove unit 16-3, the second dummy connecting line L2 passes through the notch 18 in one of the third orthographic projections 17 and the second orthographic projection 15 in the other one of the third orthographic projections 17. In the third orthographic projections 17 corresponding to the second groove unit 16-2 and the third groove unit 16-3, the third dummy connecting line L3 passes through the notch 18 in one of the third orthographic projections 17 and the second orthographic projection 15 in the other one of the third orthographic projections 17.

That is to say, between the positions where the minimum distance between any two adjacent openings 8 is achieved, only one gap in one groove unit 16 and the groove 10 in the other groove unit 16 are provided.

Further, the notches 18 in the third orthographic projection 17 corresponding to the first groove unit 16-1 include a first notch 19 and a second notch 20; and the notches 18 in the third orthographic projection 17 corresponding to the second groove unit 16-2 include a first notch 19 and a second notch 20. The first dummy connecting line L1 passes through the first notch 19 in the third orthographic projection 17 corresponding to either the first groove unit 16-1 or the second groove unit 16-2. Thus, the first notch 19 with a relatively large size is utilized to separate the first opening 8-1 and the second opening 8-2, avoiding the problem of insufficient layout space for the groove 10 due to the relatively small distance between the first opening 8-1 and the second opening 8-2.

In the above-mentioned structure, the groove 10 is provided between the positions where the minimum distance between any two adjacent openings 8 is achieved, which can effectively block the lateral leakage currents at these positions. Meanwhile, each groove unit 16 is provided with a relatively large number of gaps, which can maximize the current flow of the lateral cathode signals. Thus, the light leakage problem is improved while simultaneously addressing the voltage drop issue of the cathode signals.

Further, referring again to FIG. 14, the third orthographic projections 17 corresponding to the first groove unit 16-1, the second groove unit 16-2, and the third groove unit 16-3 each have three notches 18. The design of this number of notches 18 is more reasonable, and on the premise of ensuring a good current flow effect of the cathode signals, the improvement of the light leakage problem can be better achieved.

For the structure illustrated in FIG. 14, the present application has also tested the light leakage conditions under this structure.

In the structure illustrated in FIG. 14, the first groove unit 16-1, the second groove unit 16-2, and the third groove unit 16-3 each include three gaps. Here, a single-groove design is adopted between the positions where the minimum distance between the first opening 8-1 and the second opening 8-2 is achieved; a single-groove design is adopted between the positions where the minimum distance between the first opening 8-1 and the third opening 8-3 is achieved; and a single-groove design is adopted between the positions where the minimum distance between the second opening 8-2 and the third opening 8-3 is achieved.

The light leakage conditions of the structure illustrated in FIG. 14 are shown in Table 5. It can be seen from Table 5 that the light leakage conditions of the sub-pixels under this structure are also relatively weak. Though the improvement effect is slightly lower than that of the structure illustrated in FIGS. 10 to 13 due to the relatively large number of notches 18, the light leakage problem is still effectively improved compared with the related technology.

TABLE 5

| Light Leakage Simulation | | The structure illustrated in FIG. 14 |
|---|---|---|
| Light Leakage | R@B image | 0.0064 |
| | G@B image | 0.0046 |
| | R@G image | 0.007 |
| Uniformity of | R@B image | 99.5% |
| Light Leakage | G@B image | 99.5% |
| | R@G image | 99.5% |

In a feasible implementation, referring again to FIGS. 15 and 16, the pixel definition layer 6 includes groove units 16, and a respective groove unit 16 includes at least one groove 10 and surrounds one opening 8.

A periphery of the third opening 8-3 is surrounded by one groove unit 16, a periphery of one of the first opening 8-1 and the second opening 8-2 is surrounded by one groove unit 16, and a periphery of the other one of the first opening 8-1 and the second opening 8-2 is not surrounded by any groove unit 16.

For example, referring to FIG. 15, the groove unit 16 includes a first groove unit 16-1 surrounding the first opening 8-1 and a third groove unit 16-3 surrounding the third opening 8-3, while the periphery of the second opening 8-2 is not surrounded by any groove unit 16. Between the positions where the minimum distance between the first opening 8-1 and the second opening 8-2 is achieved, the groove 10 in the first groove unit 16-1 is provided; that is to say, the first dummy connecting line L1 passes through the second orthographic projection 15 in the third orthographic projection 17 corresponding to the first groove unit 16-1.

Alternatively, referring to FIG. 16, the groove unit 16 includes a second groove unit 16-2 surrounding the second opening 8-2 and a third groove unit 16-3 surrounding the third opening 8-3, while the periphery of the first opening 8-1 is not surrounded by any groove unit 16. Between the positions where the minimum distance between the first opening 8-1 and the second opening 8-2 is achieved, the groove 10 in the second groove unit 16-2 is provided; that is to say, the first dummy connecting line L1 passes through the second orthographic projection 15 in the third orthographic projection 17 corresponding to the second groove unit 16-2.

This design reduces the number of the grooves 10 provided between the positions where the minimum distance between the first opening 8-1 and the second opening 8-2 is achieved by not providing grooves 10 at the periphery of the first opening 8-1 or the second opening 8-2. In this structure, since the total number of the grooves 10 is relatively small, it is more conducive to optimizing the current flow of the cathode signals, and the voltage drop of the cathode signals can be lower.

For the various structures illustrated in FIGS. 15 and 16, the present application also tests the light leakage conditions of these structures.

In the structure illustrated in FIG. 15, the peripheries of the first opening 8-1 and the third opening 8-3 are surrounded by the groove units 16, while the periphery of the second opening 8-2 is not surrounded by any groove unit 16. A single-groove design is adopted between the positions where the minimum distance between the first opening 8-1 and the second opening 8-2 is achieved; a double-groove design is adopted between the positions where the minimum distance between the first opening 8-1 and the third opening 8-3 is achieved; and a single-groove design is adopted between the positions where the minimum distance between the second opening 8-2 and the third opening 8-3 is achieved. In the structure illustrated in FIG. 16, the peripheries of the second opening 8-2 and the third opening 8-3 are surrounded by the groove units 16, while the periphery of the first opening 8-1 is not surrounded by any groove unit 16. A single-groove design is adopted between the positions where the minimum distance between the first opening 8-1 and the second opening 8-2 is achieved; a single-groove design is adopted between the positions where the minimum distance between the first opening 8-1 and the third opening 8-3 is achieved; and a double-groove design is adopted between the positions where the minimum distance between the second opening 8-2 and the third opening 8-3 is achieved.

The light leakage conditions of the structures illustrated in FIGS. 15 and 16 are shown in Tables 6 and 7, respectively. It can be seen from Tables 6 and 7 that the light leakage conditions of the sub-pixels under these two structures are relatively weak. However, the difference lies in that in the structure in FIG. 15, a double-groove is provided between the positions where the minimum distance between the first opening 8-1 and the third opening 8-3 is achieved; therefore, the light leakage conditions of the structure illustrated in FIG. 15 are slightly weaker during the “R@B image” test. In contrast, in the structure illustrated in FIG. 16, a double-groove is provided between the positions where the minimum distance between the second opening 8-2 and the third opening 8-3 is achieved; therefore, the light leakage conditions of the structure illustrated in FIG. 16 are slightly weaker during the “G@B image” test.

TABLE 6

| Light Leakage Simulation | | The structure illustrated in FIG. 15 |
|---|---|---|
| Light Leakage | R@B image | 0.0016 |
| | G@B image | 0.0066 |
| | R@G image | 0.0081 |
| Uniformity of | R@B image | 99.5% |
| Light Leakage | G@B image | 99.5% |
| | R@G image | 99.5% |

TABLE 7

| | |
|---|---|
| Light Leakage Simulation | The structure shown in FIG. 16 |

| | | |
|---|---|---|
| Light Leakage | R@B image | 0.0073 |
| | G@B image | 0.0014 |
| | R@G image | 0.0082 |
| Uniformity of | R@B image | 99.5% |
| Light Leakage | G@B image | 99.5% |
| | R@G image | 99.5% |

In a feasible implementation, referring again to FIG. 2, the third opening 8-3 does not overlap the first opening 8-1 in the second direction y, and/or the third opening 8-3 does not overlap the second opening 8-2 in the second direction y.

In this case, the inclination angle of the direction of the minimum distance between the third opening 8-3 and the first opening 8-1 (i.e., the extending direction of the second dummy connecting line L2) is relatively large, and the inclination angle of the direction of the minimum distance between the third opening 8-3 and the second opening 8-2 (i.e., the extending direction of the third dummy connecting line L3) is also relatively large, which is more conducive to adjusting the opening spacing in a more flexible manner, thereby being conducive to reducing the mutual constraints between the opening area and the opening spacing during design, enabling the display panel to simultaneously achieve better service life specifications and display specifications.

In a feasible implementation, FIG. 17 is a schematic diagram of openings 8, support posts 21, and grooves 10 according to an embodiment of the present application. As shown in FIG. 17, the pixel definition layer 6 further includes grooves 10, and the grooves 10 are provided between at least some adjacent openings 8.

The display layer 5 further includes support posts 21, and the support posts 21 are provided on one side of the pixel definition layer 6 away from the substrate 4 and between at least some adjacent third openings 8-3 along the first direction x.

The support posts 21 and the third openings 8-3 are spaced by the grooves 10 in the first direction x.

Under the overall arrangement of the openings 8, there is a larger interval between adjacent third openings 8-3 in the first direction x. Thus, the support posts 21 can be provided between at least some adjacent third openings 8-3, providing a reasonable arrangement space for the support posts 21.

A support layer can be used to support a mask plate during the fabrication process of the light-emitting layer 12. When the light-emitting device 7 is a series-connected light-emitting device, the light-emitting layer 12 includes a first light-emitting layer 12-1 and a second light-emitting layer 12-2. If a support post 21 is scratched during the evaporation of the first light-emitting layer 12-1, a low-resistance leakage current path will be formed at the scratched position of the support post 21 after the evaporation of the second light-emitting layer 12-2, which tends to cause the second light-emitting layer 12-2 at the scratched position to light up, forming a bright spot.

To this end, in the embodiment of the present application, the support posts 21 and the third openings 8-3 are spaced by the grooves 10. For example, when the third groove units 16-3 has gaps, the gaps can be located on both sides of the third openings 8-3 in the second direction y, avoiding alignment with the support posts 21. Then, the grooves 10 are used to cut off the leakage current path formed by the scratch on the support post 21, thereby preventing the occurrence of the light leakage caused by the support post 21.

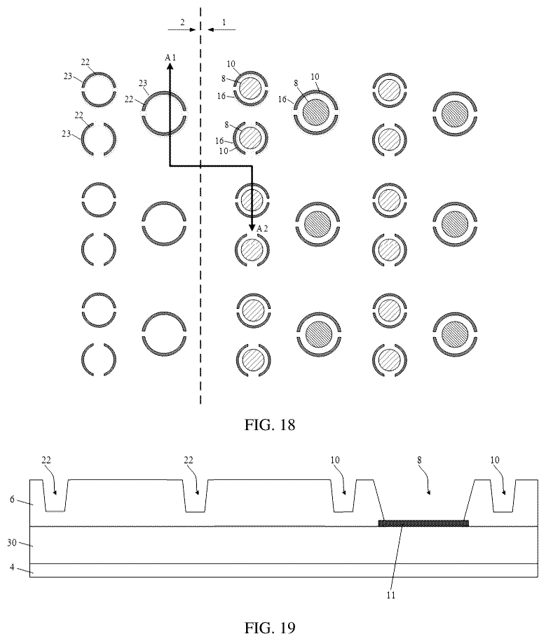

In a feasible implementation, FIG. 18 is a schematic diagram of openings 8, grooves 10, and dummy grooves according to an embodiment of the present application. As shown in FIG. 18, the pixel definition layer 6 includes grooves 10 located in the display region 1, and the grooves 10 are provided between at least some adjacent openings 8.

The pixel definition layer 6 further includes dummy grooves 22 located in the non-display region 2, and these dummy grooves 22 can be close to the edge positions of the display region 1. Adding the dummy grooves 22 in the non-display region 2 helps to improve the process uniformity, structural stability, and performance consistency of film layer fabrication, thereby increasing the morphological consistency of the grooves 10 and optimizing the uniformity of low-grayscale display.

Further, FIG. 19 is a cross-sectional view taken along an A1-A2 direction in FIG. 18. As shown in FIG. 19, the pixel definition layer 6 includes groove units 16 located in the display region 1, and a respective groove unit 16 includes at least one groove 10 and surrounds one opening 8.

The pixel definition layer 6 further includes dummy groove units 23 located in the non-display region 2, a respective dummy groove unit 23 includes at least one dummy groove 22, and orthographic projections of the dummy groove units 23 onto the substrate 4 have a same shape as orthographic projections of at least some groove units 16 onto the substrate 4. Portions in the pixel definition layer 6 that are surrounded by the dummy groove units 23 have no openings 8.

That is to say, this portion of the pixel definition layer 6 in the non-display region 2 may only be provided with dummy groove units 23 consistent in pattern with the groove units 16, without being provided with dummy openings 8. This can avoid exerting significant adverse effects on the leveling effect of the organic encapsulation material in the non-display region 2 during subsequent encapsulation, thereby preventing the deterioration of edge pits that would seriously affect the encapsulation effect.

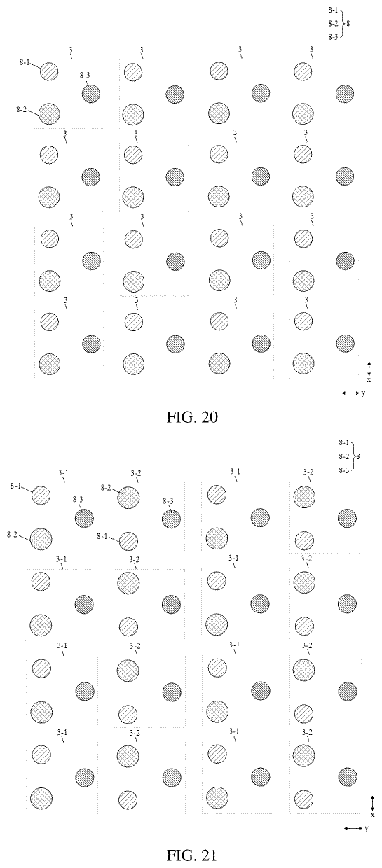

In a feasible implementation, FIG. 20 is still another schematic diagram of a display panel according to an embodiment of the present application. As shown in FIG. 20, in a plurality of pixel regions 3 arranged along the second direction y, the first openings 8-1 of the plurality of pixel regions 3 are arranged along the second direction y, and the second openings 8-2 of the plurality of pixel regions 3 are arranged along the second direction y.

Alternatively, FIG. 21 is still another schematic diagram of a display panel according to an embodiment of the present application. As shown in FIG. 21, a plurality of pixel regions 3 arranged along the second direction y includes first pixel regions 3-1 and second pixel regions 3-2 alternatively arranged, where the first openings 8-1 of the first pixel regions 3-1 and the second openings 8-2 of the second pixel regions 3-2 are arranged along the second direction y, and the second openings 8-2 of the first pixel regions 3-1 and the first openings 8-1 of the second pixel regions 3-2 are arranged along the second direction y.

Based on the technical solutions according to the embodiments of the present application, the above arrangements can enable the display panel to achieve better performance.

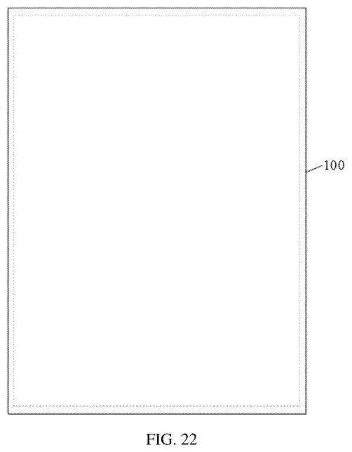

Based on the same inventive concept, an embodiment of the present application further provides a display apparatus. FIG. 22 is a schematic structural diagram of a display apparatus according to an embodiment of the present application. As shown in FIG. 22, the display apparatus includes the above-mentioned display panel 100. Of course, the display apparatus shown in FIG. 22 is merely illustrative, and the display apparatus may be any electronic device with a display function, such as a mobile phone, a tablet computer, a laptop computer, an e-reader, or a television.

The above are merely preferred embodiments of the present application, and are not intended to limit the present application. Any modifications, equivalent substitutions, improvements, etc., made within the spirit and principle of the present application shall all fall within the protection scope of the present application.

Finally, it should be noted that the above embodiments are only used to illustrate the technical solutions of the present application, rather than limiting them. Although the present application has been described in detail with reference to the above embodiments, those of skill in the art should understand that they can still modify the technical solutions recited in the above embodiments, or make equivalent substitutions for some or all of the technical features thereof; and these modifications or substitutions do not make the essence of the corresponding technical solutions depart from the scope of the technical solutions of the various embodiments of the present application.

What is claimed is:

1. A display panel, comprising:
a display region and a non-display region, wherein the display region comprises a plurality of pixel regions;
a substrate; and
a display layer located on one side of the substrate, wherein the display layer comprises a pixel definition layer and a plurality of light-emitting devices, the pixel definition layer comprises a plurality of openings, and at least a portion of a respective light-emitting device is located within one of the openings; the plurality of openings comprise a first opening, a second opening, and a third opening that respectively correspond to the light-emitting devices of different colors, and a respective pixel region comprises one first opening, one second opening, and one third opening;
wherein orthographic projections of the openings onto the substrate are first orthographic projections, and the first orthographic projections comprise a first orthographic sub-projection corresponding to the first opening, a second orthographic sub-projection corresponding to the second opening, and a third orthographic sub-projection corresponding to the third opening;
in the pixel region, the first opening and the second opening are arranged along a first direction, the third opening does not overlap the first opening and the second opening in the first direction, a virtual straight line extending along a second direction and passing through a center point of the third orthographic sub-projection is located between the first orthographic sub-projection and the second orthographic sub-projection, and the second direction intersects with the first direction;
in the pixel region, a distance between two points that are closest to each other in the first orthographic sub-projection and the second orthographic sub-projection is a first distance; a distance between two points that are closest to each other in the first orthographic sub-projection and the third orthographic sub-projection is a second distance, and edges on which the two points are located are curved edges; and a distance between two points that are closest to each other in the second orthographic sub-projection and the third orthographic sub-projection is a third distance, and edges on which the two points are located are curved edges; and
the second distance is greater than the first distance, and the third distance is greater than the first distance.

2. The display panel according to claim 1, wherein
shapes of the first orthographic sub-projection, the second orthographic sub-projection, and the third orthographic sub-projection are circular.

3. The display panel according to claim 1, wherein
a shape of at least one of the first orthographic sub-projection, the second orthographic sub-projection, and the third orthographic sub-projection is elliptical.

4. The display panel according to claim 1, wherein
the light-emitting devices comprise a green light-emitting device, and at least a portion of the green light-emitting device is located within the second opening; and
an area of the second orthographic sub-projection is greater than an area of the first orthographic sub-projection, and/or the area of the second orthographic sub-projection is greater than an area of the third orthographic sub-projection.

5. The display panel according to claim 1, wherein
the pixel definition layer further comprises grooves, and the grooves are provided between at least some adjacent openings;
orthographic projections of the grooves onto the substrate are second orthographic projections;
in the pixel region, a first dummy connecting line is provided between two points that are closest to each other in the first orthographic sub-projection and the second orthographic sub-projection, a second dummy connecting line is provided between two points that are closest to each other in the first orthographic sub-projection and the third orthographic sub-projection, and a third dummy connecting line is provided between two points that are closest to each other in the second orthographic sub-projection and the third orthographic sub-projection; and
a number of the second orthographic projections passed through by the first dummy connecting line is less than or equal to a number of the second orthographic projections passed through by the second dummy connecting line, and the number of the second orthographic projections passed through by the first dummy connecting line is less than or equal to a number of the second orthographic projections passed through by the third dummy connecting line.

6. The display panel according to claim 5, wherein
the number of the second orthographic projections passed through by the second dummy connecting line is greater than the number of the second orthographic projections passed through by the first dummy connecting line; and/or
the number of the second orthographic projections passed through by the third dummy connecting line is greater than the number of the second orthographic projections passed through by the first dummy connecting line.

7. The display panel according to claim 5, wherein
the pixel definition layer comprises groove units, a respective groove unit comprises at least one groove and surrounds one opening;
orthographic projections of the groove units onto the substrate are third orthographic projections, a respective third orthographic projection comprises at least one second orthographic projection, and at least some third orthographic projections have a notch; and
the first dummy connecting line passes through the notch of at least one third orthographic projection.

8. The display panel according to claim 7, wherein
the notch comprises a first notch and a second notch, and the first dummy connecting line passes through the first notch but does not pass through the second notch; and
a length of the first notch in an extension direction of the third orthographic projection in which the first notch is located is greater than a length of the second notch in the extension direction of the third orthographic projection in which the second notch is located.

9. The display panel according to claim 7, wherein
in at least one third orthographic projection, the notch is located on at least one side of the first orthographic projection surrounded by the notch in the first direction; and in at least one third orthographic projection, the notch is located on at least one side of the first orthographic projection surrounded by the notch in the second direction.

10. The display panel according to claim 7, wherein
the groove units comprise a first groove unit surrounding the first opening and a second groove unit surrounding the second opening;
the third orthographic projection corresponding to at least one first groove unit has one notch, and/or the third orthographic projection corresponding to at least one first groove unit has at least two notches; and
the third orthographic projection corresponding to at least one second groove unit has one notch, and/or the third orthographic projection corresponding to at least one second groove unit has at least two notches.

11. The display panel according to claim 10, wherein
the third orthographic projection corresponding to the first groove unit has two notches, and the third orthographic projection corresponding to the second groove unit has two notches; and
in the third orthographic projection corresponding to the first groove unit, the two notches are located on opposite sides of the first orthographic sub-projection in a third direction, respectively, and in the third orthographic projection corresponding to the second groove unit, the two notches are located on opposite sides of the second orthographic sub-projection in a fourth direction, respectively; wherein one of the third direction and the fourth direction is parallel to the first direction, and the other one of the third direction and the fourth direction is parallel to the second direction.

12. The display panel according to claim 10, wherein
the third orthographic projection corresponding to the first groove unit has one notch, and the third orthographic projection corresponding to the second groove unit has one notch; and
in the third orthographic projections corresponding to the first groove unit and the second groove unit, each notch is located on a same side of the first orthographic projection surrounded by the notch in the first direction.

13. The display panel according to claim 10, wherein
the groove units further comprise a third groove unit surrounding one third opening; and
the third groove unit comprises at least one groove, and the third orthographic projection corresponding to the third groove unit has at least one notch.

14. The display panel according to claim 1, wherein
the pixel definition layer comprises groove units, and a respective groove unit comprises at least one groove and surrounds one opening; and
a periphery of the third opening is surrounded by one groove unit, a periphery of one of the first opening and the second opening is surrounded by one groove unit, and a periphery of the other one of the first opening and the second opening is not surrounded by any groove unit.

15. The display panel according to claim 1, wherein
the third opening does not overlap the first opening in the second direction, and/or the third opening does not overlap the second opening in the second direction.

16. The display panel according to claim 1, wherein
the pixel definition layer further comprises grooves, and the grooves are provided between at least some adjacent openings;
the display layer further comprises support posts, and the support posts are provided on one side of the pixel definition layer away from the substrate and between at least some adjacent third openings along the first direction; and
the support posts and the third openings are spaced by the grooves in the first direction.

17. The display panel according to claim 1, wherein
the pixel definition layer comprises grooves located in the display region, and the grooves are provided between at least some adjacent openings; and
the pixel definition layer further comprises dummy grooves located in the non-display region.

18. The display panel according to claim 17, wherein
the pixel definition layer comprises groove units located in the display region, and a respective groove unit comprises at least one groove and surrounds one opening; and
the pixel definition layer further comprises dummy groove units located in the non-display region, a respective dummy groove unit comprises at least one dummy groove, and orthographic projections of the dummy groove units onto the substrate have a same shape as orthographic projections of at least some groove units onto the substrate, and portions in the pixel definition layer that are surrounded by the dummy groove units do not have the opening.

19. The display panel according to claim 1, wherein
in a plurality of pixel regions arranged along the second direction, the first openings of the plurality of pixel regions are arranged along the second direction, and the second openings of the plurality of pixel regions are arranged along the second direction; or
a plurality of pixel regions arranged along the second direction comprise first pixel regions and second pixel regions alternatively arranged, wherein the first openings of the first pixel regions and the second openings of the second pixel regions are arranged along the second direction, and the second openings of the first pixel regions and the first openings of the second pixel regions are arranged along the second direction.

20. A display apparatus, comprising a display panel, wherein the display panel comprises:
a display region and a non-display region, wherein the display region comprises a plurality of pixel regions;
a substrate; and
a display layer located on one side of the substrate, where the display layer comprises a pixel definition layer and a plurality of light-emitting devices, the pixel definition layer comprises a plurality of openings, and at least a portion of a respective light-emitting device is located within one of the openings; the plurality of openings comprise a first opening, a second opening, and a third opening that respectively correspond to the light-emitting devices of different colors, and a respective pixel region comprises one first opening, one second opening, and one third opening;
wherein orthographic projections of the openings onto the substrate are first orthographic projections, and the first orthographic projections comprise a first orthographic sub-projection corresponding to the first opening, a second orthographic sub-projection corresponding to the second opening, and a third orthographic sub-projection corresponding to the third opening;
in the pixel region, the first opening and the second opening are arranged along a first direction, the third opening does not overlap the first opening and the second opening in the first direction, a virtual straight line extending along a second direction and passing through a center point of the third orthographic sub-projection is located between the first orthographic sub-projection and the second orthographic sub-projection, and the second direction intersects with the first direction;
in the pixel region, a distance between two points that are closest to each other in the first orthographic sub-projection and the second orthographic sub-projection is a first distance; a distance between two points that are closest to each other in the first orthographic sub-projection and the third orthographic sub-projection is a second distance, and edges on which the two points are located are curved edges; and a distance between two points that are closest to each other in the second orthographic sub-projection and the third orthographic sub-projection is a third distance, and edges on which the two points are located are curved edges; and
the second distance is greater than the first distance, and the third distance is greater than the first distance.
